(19) United States
(12) Patent Application Publication
(10) Pub. No.: US 2011/0062561 A1
(43) Pub. Date: Mar. 17, 2011

(54) SEMICONDUCTOR DEVICE AND METHOD OF MANUFACTURING THE SAME

(75) Inventors: Nao AKIYAMA, Oita-ken (JP); Seiji INUMIYA, Hopewell Junction, NY (US)

(73) Assignee: Kabushiki Kaisha Toshiba, Tokyo (JP)

(21) Appl. No.: 12/880,009

(22) Filed: Sep. 10, 2010

(30) Foreign Application Priority Data
Sep. 11, 2009 (JP) P2009-210548

(51) Int. Cl. H01L 21/314; H01L 29/00

(52) U.S. Cl. 257/637; 438/478; 438/763; 257/E29.001; 257/E21.266

(57) ABSTRACT

A method of manufacturing a semiconductor device comprising: forming a p type region and an n type region in a main surface of a semiconductor substrate, the p type region and the n type region being insulated from each other with an element-isolation region; forming a first insulating film on the p type region and on the n type region, the first insulating film being made of any one of a silicon oxide film and a silicon oxynitride film; forming a lanthanum oxide film on the first insulating film on the p type region; forming a second insulating film both on the lanthanum oxide film on the p type region and on the first insulating film on the n type region, the second insulating film containing any one of hafnium and zirconium; and forming a titanium nitride film on the second insulating film, the titanium nitride film satisfying TiₓN_{y} where x/y<1.

### CROSS REFERENCE TO RELATED APPLICATION

This application is based upon and claims the benefit of priority from Japanese Patent Application No. 2009-210548, filed on Sep. 11, 2009, the entire contents of which are incorporated herein by reference.

### BACKGROUND

The invention relates to a semiconductor device, and particularly to a semiconductor device including a complementary metal oxide semiconductor field effect transistor (CMOSFET) using a metal gate electrode, and to a method of manufacturing the semiconductor device.

The ongoing miniaturization of large-scale integrated circuit requires the gate insulating films to be formed thinner and thinner. Complementary metal oxide semiconductors (CMOSs) of 32-nm node or later need a gate insulating film with an equivalent SiO₂ thickness of 0.9 nm.

Polycrystalline silicon (Poly-Si) gate electrodes are conventionally used as the gate electrodes. Poly-Si gate electrodes are depleted due to their semiconductor characteristics. The depletion of the poly-Si gate electrodes increases the effective film thicknesses of the gate insulating films, and thus impedes the thinning of the gate insulating films. This calls for introduction of metal gate electrodes to avoid the depletion that occurs when poly-Si gate electrodes are used.

To reduce the threshold voltage (Vth) of a transistor, each metal gate electrode is required to have an effective work function (EWF) around the Si band edge. Specifically, the EWF around Si conduction band edge (4.05 eV) is required in the case of N channel metal oxide semiconductor field effect transistors (NMOSFETs), whereas the EWF around Si valence band edge (5.17 eV) is required in the case of P channel metal oxide semiconductor field effect transistors (PMOSFETs). Achieving the EWF at the Si band edge leads to a reduction in the threshold voltage, and thus a desirable driving power for the CMOS can be obtained.

At present, titanium nitride (TiN) is widely studied as a candidate material for metal gate electrodes because TiN is thermally stable and allows easy gate processing. It is known that TiN on a high-k insulating film has an EWF around the mid gap of Si band gap. Accordingly, the use of this technique alone cannot achieve a sufficiently low threshold voltage.

A technique for reducing the threshold voltage as follows has already been disclosed (see, for example, Published Japanese Translation of PCT International Application No. 2005-527974). In this technique, the flat-band voltage (VFB) is shifted to the negative side, that is, the EWF is reduced, by selectively introducing a lanthanum oxide film (cap film) at the interface of titanium nitride electrode/high-k gate insulating film in an NMOSFET region.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a sectional view taken in the channel-length direction, illustrating a semiconductor device according to an embodiment of the invention.

FIG. 2 is a sectional view taken in the channel-length direction, illustrating the semiconductor device according to the embodiment of the invention.

FIGS. 3A to 3C show schematic views illustrating processes in a method of manufacturing a semiconductor device according to an embodiment of the invention.

FIGS. 4A to 4C show schematic views illustrating processes in the method of manufacturing a semiconductor device according to the embodiment of the invention.

FIGS. 5A and 5B show schematic views illustrating processes in the method of manufacturing a semiconductor device according to the embodiment of the invention.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

The method of manufacturing a semiconductor device according to one aspect of the invention includes: forming a p type region and an n type region in a main surface of a semiconductor substrate, the p type region and the n type region being insulated from each other with an element-isolation region; forming a first insulating film on the p type region and on the n type region, the first insulating film being made of a silicon oxide film or a silicon oxynitride film; forming a lanthanum oxide film on the first insulating film on the p type region; forming a second insulating film both on the lanthanum oxide film on the p type region and on the first insulating film on the n type region, the second insulating film containing hafnium or zirconium; and forming a titanium nitride film on the second insulating film, the titanium nitride film satisfying TiₓN_{y} where x/y<1.

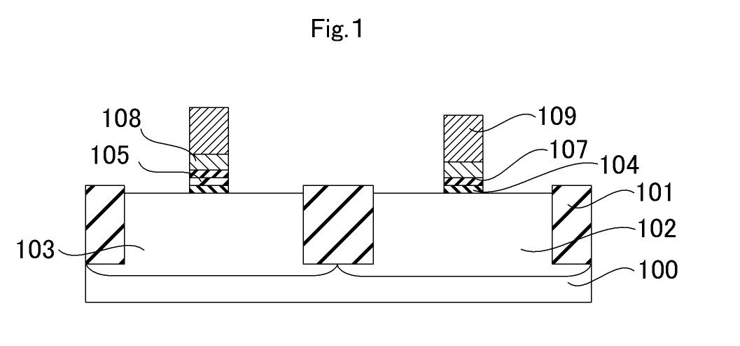

FIG. 1 is a sectional view taken in the channel-length direction, illustrating a semiconductor device according to an embodiment of the invention. Element-isolation regions 101 each with a depth ranging from 200 nm to 350 nm are formed on a monocrystal silicon substrate 100. Active device areas are formed by the subdivision with the element-isolation regions 101.

An n type diffusion region 102 where a PMOSFET is to be formed (hereafter, simply referred to as a PMOS region) and a p type diffusion region 103 where an NMOSFET is to be formed (hereafter, simply referred to as an NMOS region) are formed in the active device areas. The n type diffusion region 102 typically has an impurity (phosphorus) concentration of approximately 3×10¹³ cm⁻³ whereas the p type diffusion region 103 typically has an impurity (boron) concentration of approximately 2×10¹³ cm⁻³.

A silicon oxide film 104 is formed on the NMOS region of the monocrystal silicon substrate 100, and a lanthanum oxide film 105 is formed on the silicon oxide film 104. In this embodiment, atoms of lanthanum are not diffused from the cap layer. Instead, the lanthanum oxide film 105 containing only lanthanum atoms of a necessary amount for the reduction of the threshold value is formed above the monocrystal silicon substrate 100, so that the threshold voltage can be adjusted with accuracy.

A hafnium silicon oxynitride film 107 is formed on the lanthanum oxide film 105. The hafnium silicon oxynitride film 107 is an insulating film that is higher in permittivity than silicon oxide films, silicon oxynitride films, silicon nitride films, and the like. The silicon oxide film 104 and the hafnium silicon oxynitride film 107 serve as gate insulating films.

A silicon oxide film 104 is formed on the PMOS region of the monocrystal silicon substrate 100, and a hafnium silicon oxynitride film 107 is formed on the silicon oxide film 104. The hafnium silicon oxynitride film 107 is an insulating film that is higher in permittivity than silicon oxide films, silicon oxynitride films, silicon nitride films, and the like. The silicon oxide film 104 and the hafnium silicon oxynitride film 107 serve as gate insulating films.

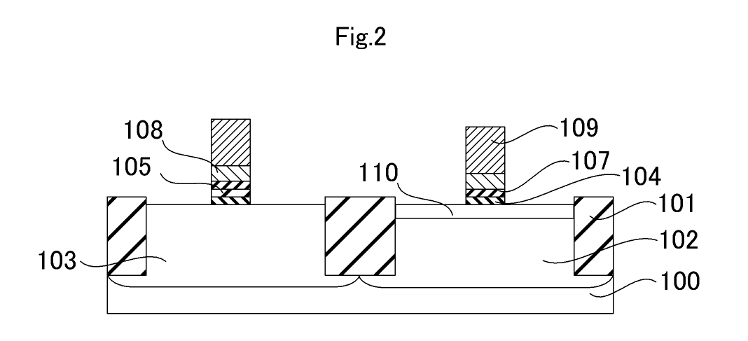

As FIG. 2 shows, a silicon germanide epitaxial layer 110 may be formed on the surface of the PMOS region of the monocrystal silicon substrate 100. The use of the silicon germanide epitaxial layer 110 grown over the PMOS region can raise the apparent effective work function and lower the threshold voltage of the PMOSFET in comparison to a case of the silicon substrate 100 used alone without the silicon germanide epitaxial layer 110. While the silicon germanide epitaxial layer 110 is being grown, impurities such as boron may be doped to adjust the threshold voltage of the PMOSFET.

A titanium nitride film 108 is formed on each of the hafnium silicon oxynitride films 107 in the NMOS region and the PMOS region, and a poly-Si film 109 is formed on each of the titanium nitride films 108. The titanium nitride film 108 is a film of TiₓN_{y} where x/y<1. To put it differently, the titanium nitride film 108 contains more nitrogen atoms than titanium atoms. Thus, in this embodiment, the titanium nitride film 108 formed in the PMOS region has the same ratio of nitride atoms to titanium atoms as that of the titanium nitride film 108 formed in the NMOS region.

In this embodiment, by forming each titanium nitride film 108 so as to contain more nitrogen atoms than titanium atoms, the excessive nitrogen atoms contained in the titanium nitride film 108 diffuse into the interface between the hafnium silicon oxynitride film 107 and the silicon oxide film 104, and thus fixed negative charges are formed. The fixed negative charges have an effect to make the titanium nitride film 108 function as a metal gate material with a large effective work function, so that a PMOSFET with a low (meaning that having a small absolute value) threshold voltage can be obtained.

In addition, since the lanthanum oxide film 105 is formed between the silicon oxide film 104 and the hafnium silicon oxynitride film 107 in the NMOS region, an electric dipole is formed at the interface between the lanthanum oxide film 105 and the silicon oxide film 104. Accordingly, an NMOSFET with a low (meaning that having a small absolute value) threshold voltage can be obtained.

In addition, since the lanthanum oxide film 105 is formed directly on the silicon oxide film 104, the excessive nitrogen atoms contained in the titanium nitride film 108 diffuse into the interface between the hafnium silicon oxynitride film 107 and the silicon oxide film 104 in the NMOS region. Accordingly, the fixed negative charges that would raise the threshold voltage can be prevented from being formed in the NMOSFET.

In addition, if the silicon germanide epitaxial layer 110 is formed on the surface of the PMOS region of the monocrystal silicon substrate 100, the PMOSFET thus obtained has a still lower (meaning that having a small absolute value) threshold voltage. Accordingly, it is preferable to form the silicon germanide epitaxial layer 110 as such.

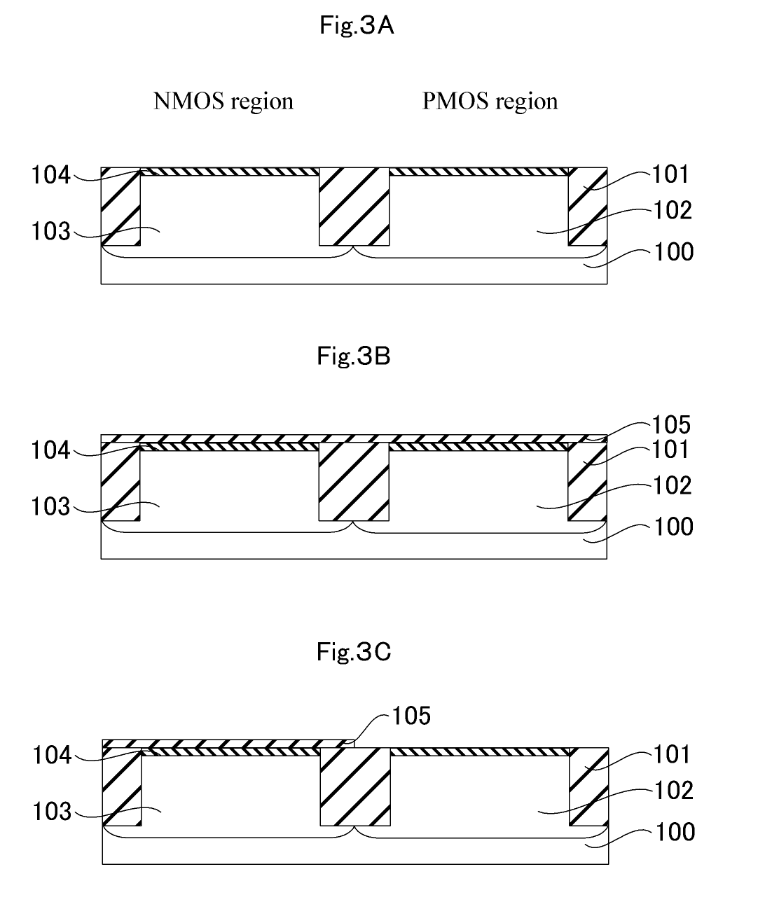

FIGS. 3A to 5B are sectional views schematically illustrating processes of manufacturing the semiconductor device according to the embodiment of the invention. A method of manufacturing a semiconductor device according to an embodiment of the invention will be described by referring to FIGS. 3A to 5B.

Firstly, as FIG. 3A shows, a main surface of a monocrystal silicon substrate 100 is partitioned with element-isolation regions 101 to form an n type diffusion region 102, which is a PMOS region, and a p type diffusion region 103, which is an NMOS region. A silicon oxide film 104 with a thickness of approximately 1.0 nm is formed on the silicon substrate 100 by either the thermal oxidation method or radical oxidation method. A silicon oxynitride film or the like may be formed in place of the silicon oxide film 104.

Then, as FIG. 3B shows, a lanthanum oxide film 105 is formed on the silicon oxide film 104 by, for example, the PVD method. After the formation of the lanthanum oxide film 105, the lanthanum oxide film 105 formed over the NMOS region is protected by selectively forming a photoresist film or the like over the NMOS region. Meanwhile, the lanthanum oxide film 105 formed over the PMOS region is removed using a diluted hydrochloric acid solution, or the like (see FIG. 3C).

The lanthanum oxide film 105 is a hygroscopic film, and therefore exposing the lanthanum oxide film 105 to the air for a long time causes degradation of the film quality. For this reason, the above-described process is desirably finished within three hours, or preferably within half an hour, from the time when the lanthanum oxide film 105 is formed and then exposed to the air.

In addition, if the wet processing to remove the lanthanum oxide film 105 over the PMOS region by any chance causes degradation of the film quality of the silicon oxide film 104, the silicon oxide film 104 over the PMOS region may be removed together with the lanthanum oxide film 105, and another silicon oxide film may be formed over the PMOS region.

Note that, by growing a silicon germanide layer over the PMOS region, the apparent effective work function can be raised and the threshold voltage of the PMOSFET can be lowered in comparison to a case of using a silicon substrate as the channel for the PMOSFET. While the silicon germanide layer 110 is being grown, impurities such as boron may be doped to adjust the threshold voltage of the PMOSFET.

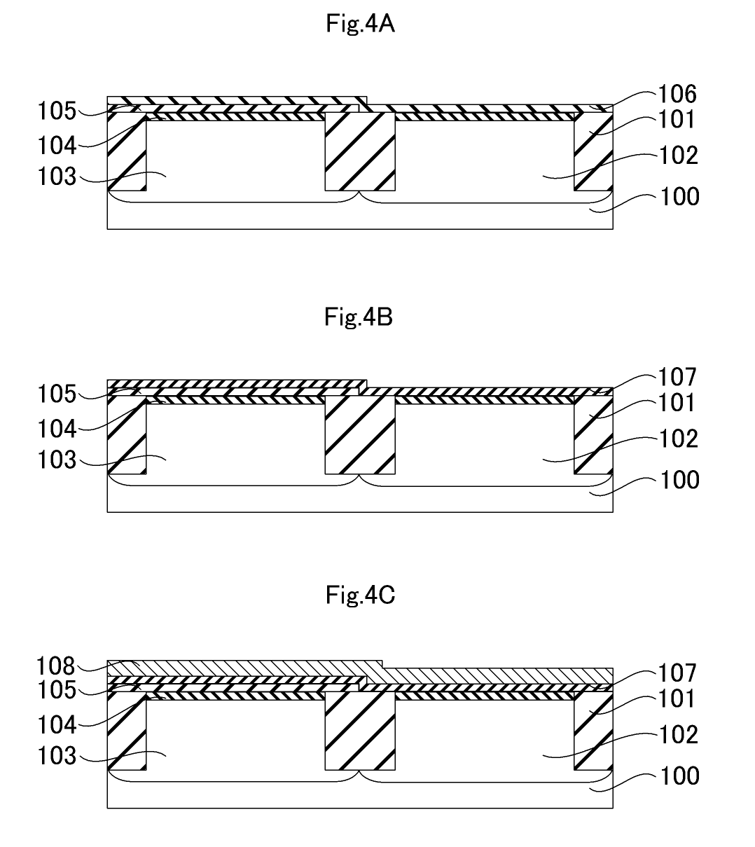

Then, as FIG. 4A shows, a hafnium silicon oxide film 106 with a thickness of, for example, 2 nm is formed by the CVD method or the like both on the lanthanum oxide film 105 and on the silicon oxide film 104 over the PMOS region. Nitrogen atoms are introduced into the hafnium silicon oxide film 106 by the plasma nitridation method.

After the introduction of nitrogen into the hafnium silicon oxide film 106 by the plasma nitridation method, the introduced nitrogen atoms are stabilized within the film by a heat treatment performed, for example, at 1000° C. and 5 torr for 10 seconds. Thus, a hafnium silicon oxynitride film 107 is formed (see FIG. 4B).

Then, as FIG. 4C shows, a titanium nitride film 108 to be gate electrodes is deposited by, for example, the PVD method. The thickness of the titanium nitride film 108 thus deposited is approximately 7 nm.

The composition of the titanium nitride film 108 can be controlled by adjusting the N₂ flow rate in the atmosphere while titanium is being deposited on the hafnium silicon oxynitride film 107 by sputtering. Specifically in this embodiment, the N₂ flow rate in the atmosphere is adjusted so that the titanium nitride film 108 contains more nitride atoms than titanium atoms (i.e., TiₓN_{y} where x/y<1).

The excessive nitrogen atoms contained in the titanium nitride film 108 diffuse into the interface between the hafnium silicon oxynitride film 107 and the silicon oxide film 104, and thus fixed negative charges are formed.

The fixed negative charges have an effect to allow the titanium nitride film 108 to serve as a metal gate material with a large effective work function, so that a PMOSFET with a low (meaning that having a small absolute value) threshold voltage can be obtained.

In this embodiment, the titanium nitride film 108 is formed also over the NMOS region. Specifically, the titanium nitride film 108 formed over the NMOS region has the same ratio of nitrogen atoms to titanium atoms as that of the titanium nitride film 108 formed over the PMOS region. Hence, as in the case of the PMOS region, the excessive nitrogen atoms diffuse into the interface between the lanthanum oxide film 105 and the silicon oxide film 104.

According to a conventional technique, a lanthanum oxide film is formed at the interface between the hafnium silicon oxynitride film 107 and the titanium nitride film 108, and lanthanum atoms are made to diffuse into the interface between the silicon oxide film 104 and the hafnium silicon oxynitride film 107 so as to control the threshold voltage of an NMOSFET.

In the case of this conventional technique, the excessive nitrogen atoms diffused into the interface between the silicon oxide film 104 and the hafnium silicon oxynitride film 107 of the NMOSFET form fixed negative charges, resulting in a problem of degrading the characteristics of the NMOSFET.

In this embodiment, however, the lanthanum oxide film 105 is formed directly on the silicon oxide film 104 over the NMOS region. By forming the lanthanum oxide film 105 directly on the silicon oxide film 104, the excessive nitrogen atoms diffused from the titanium nitride film 108 are prevented from forming fixed negative charges.

In addition, by forming the titanium nitride films 108 with the same ratio of nitride atoms to titanium atoms both over the PMOS region and over the NMOS region, it is not necessary to form gate electrodes with different work functions over the PMOS region and over the NMOS region, so that the number of manufacturing processes can be reduced.

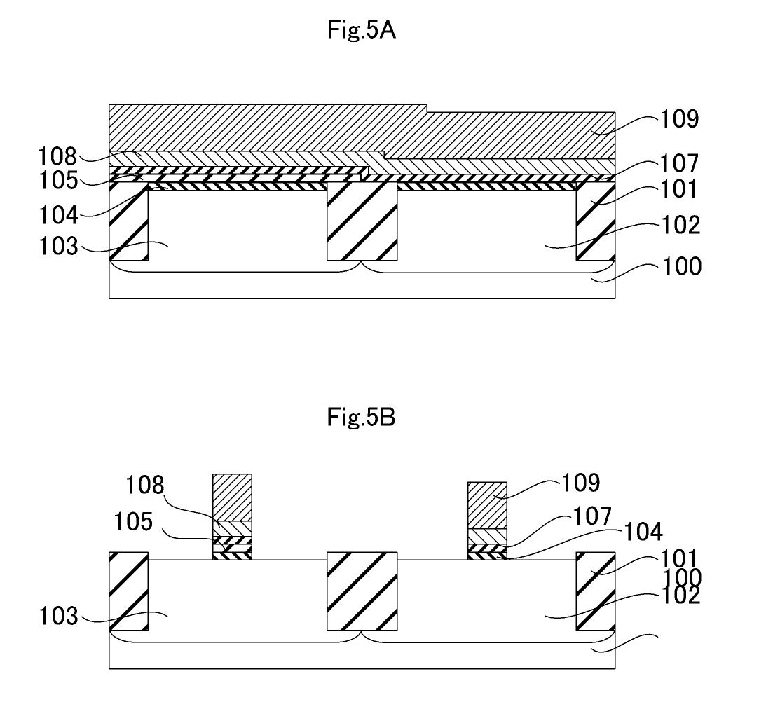

After the formation of the titanium nitride film 108, a poly-Si film 109 to be the gate electrodes is formed on the titanium nitride film 108 as FIG. 5A shows. The poly-Si film 109 has a thickness of approximately 70 nm. Each gate electrode in this embodiment has a laminate structure including the titanium nitride film 108 and the poly-Si film 109.

Then, as FIG. 5B shows, the laminate films are etched by the RIE method into the shapes of the gate electrodes, and thus the structures of gate stacks are completed.

In this embodiment, since the lanthanum oxide film 105 is used to control the threshold value for the NMOSFET, the thickness of the lanthanum oxide film 105 can be adjusted to meet the demands for the device. For example, if a low threshold voltage is demanded, the lanthanum oxide film 105 has to be thicker.

If, in contrast, the threshold voltage demanded for the device is not very low, the lanthanum oxide film 105 may be replaced with an island-like structure instead of the film structure, or may be provided in the state of metal lanthanum.

In addition, in this embodiment, the hafnium silicon oxynitride film 107 is used at a side of the gate insulating film, the side being in contact with the gate electrode. The hafnium silicon oxynitride film 107 may be replaced with a hafnium oxynitride film, a zirconium oxide film, a zirconium oxynitride film, a hafnium silicon oxide film, a hafnium oxide film, a zirconium silicon oxide film, a zirconium silicon oxynitride film, a hafnium zirconium oxide film, a hafnium zirconium oxynitride film, a hafnium zirconium silicon oxide film, a hafnium zirconium silicon oxynitride film, or the like.

This embodiment has the following effects. Specifically, a PMOSFET with a low (meaning that having a small absolute value) threshold voltage is obtained in the PMOS region because of the effects of the titanium nitride film formed so as to contain more nitrogen atoms than the titanium atoms, whereas an NMOSFET with a low threshold voltage is obtained in the NMOS region because of the effects of the lanthanum oxide film.

In addition, by forming the lanthanum oxide film 105 directly on the silicon oxide film 104 over the NMOS region, the excessive nitrogen atoms diffused from the titanium nitride film 108 over the NMOS region can be prevented from forming fixed negative charges.

In addition, by forming the titanium nitride films 108 with the same ratio of nitride atoms to titanium atoms both over the PMOS region and over the NMOS region, it is not necessary to form gate electrodes with different work functions over the PMOS region and over the NMOS region, so that the number of manufacturing processes can be reduced.

It is to be noted that the present invention is not limited to the above-described embodiments and can be implemented in various modified forms without departing from the scope of the present invention.

What is claimed is:

1. A method of manufacturing a semiconductor device comprising:
forming a p type region and an n type region in a main surface of a semiconductor substrate, the p type region and the n type region being insulated from each other with an element-isolation region;
forming a first insulating film on the p type region and on the n type region, the first insulating film being made of any one of a silicon oxide film and a silicon oxynitride film;
forming a lanthanum oxide film on the first insulating film on the p type region;
forming a second insulating film both on the lanthanum oxide film on the p type region and on the first insulating film on the n type region, the second insulating film containing any one of hafnium and zirconium; and
forming a titanium nitride film on the second insulating film, the titanium nitride film satisfying TiₓN_{y} where x/y<1.

2. The method of manufacturing a semiconductor device according to claim 1, wherein nitrogen atoms contained in the titanium nitride film form fixed charges at an interface between the first insulating film and the second insulating film that are formed on the n type region.

3. The method of manufacturing a semiconductor device according to claim 1, wherein lanthanum atoms contained in the lanthanum oxide film form an electric dipole at an interface between the first insulating film and the lanthanum oxide film that are formed on the p type region.

4. The method of manufacturing a semiconductor device according to claim 1, wherein lanthanum atoms contained in the lanthanum oxide film suppress formation of fixed charges at an interface between the first insulating film and the lanthanum oxide film that are formed on the p type region.

5. The method of manufacturing a semiconductor device according to claim 1, forming a silicon germanide layer on the n type region before forming the first insulating film.

6. The method of manufacturing a semiconductor device according to claim 1, the titanium nitride film formed by PVD flowing N₂.

7. A semiconductor device comprising:
a semiconductor substrate including a p type region and an n type region that are insulated from each other;
a first gate insulating film including:
a first insulating film made of any one of a silicon oxide film and a silicon oxynitride film and formed on the p type region;
a lanthanum oxide film formed on the first insulating film; and
a second insulating film containing any one of hafnium and zirconium and formed on the lanthanum oxide film;
a second gate insulating film including:
a third insulating film made of any one of a silicon oxide film and a silicon oxynitride film and formed on the n type region; and
a fourth insulating film containing any one of hafnium and zirconium and formed on the third insulating film; and
titanium nitride films formed respectively on the first gate insulating film and on the second gate insulating film, each of the titanium nitride films satisfying TiₓN_{y} where x/y<1.

8. The semiconductor device according to claim 5, wherein the first insulating film is formed on a silicon germanide layer.

9. The semiconductor device according to claim 5, wherein the first and second gate insulating films are hafnium silicon oxynitride film.
